(19) United States
(12) Patent Application Publication
(10) Pub. No.: US 2009/0211639 A1
(43) Pub. Date: Aug. 27, 2009

(54) DYE-SENSITIZED SOLAR CELL HAVING NANOSTRUCTURE ABSORBING MULTI-WAVELENGTH, AND A METHOD FOR PREPARING THE SAME

(76) Inventors: Nam-Gyu PARK, Seoul (KR); Kyung-Kon KIM, Seoul (KR); Hyung-Jun KOO, Seoul (KR)

Correspondence Address: MCNEELY BODENDORF LLP, P.O. BOX 34175, WASHINGTON, DC, 20043, US

(21) Appl. No.: 12/393,057

(22) Filed: Feb. 26, 2009

(30) Foreign Application Priority Data
Feb. 26, 2008 (KR) 10-2008-0017070

(51) Int. Cl. H01L 31/00; H01L 31/0264

(52) U.S. Cl. 136/262; 136/252; 438/63; 257/E31.004

(57) ABSTRACT

A dye-sensitized solar cell absorbing a multi-wavelength, and a method of preparing the same are provided. In the dye-sensitized solar cell, a contacted interface structure of metal oxide nanoparticle layers of a photoelectrode and a counter electrode may be provided. The contacted interface structure may be formed by contacting the faces of the nanoparticle layers of the electrodes adsorbed by same or different dyes after forming photoabsorption layers comprising the nanoparticle layers respectively on the photoelectrode and the counter electrode.

### CROSS-REFERENCE TO RELATED APPLICATION(S)

This application claims the benefit under 35 U.S.C. §119(a) of a Korean Patent Application No. 10-2008-0017070, filed on Feb. 26, 2008 in the Korean Intellectual Property Office, the entire disclosure of which is hereby incorporated by reference.

### TECHNICAL FIELD

The following description relates to a dye-sensitized solar cell having improved photoelectric current density and efficiency, and a method of preparing the same, and more particularly, to a dye-sensitized solar cell which absorbs a broader wavelength of solar rays, wherein metal oxide nanoparticle layers adsorbed by dyes having same or different absorption wavelength are formed on a photoelectrode and a counter electrode respectively, and a contacted interface layered structure of the nanoparticle layers is formed in a single cell by combining the faces of the nanoparticle layers so as to contact each other, and a method of preparing the same.

### BACKGROUND

FIG. 1A shows a dye sensitized solar cell (or a dye-sensitized photovoltaic cell) as represented by a photoelectrochemical solar cell announced by Gratzel et al., Switzerland, in 1991. A dye-sensitized solar cell or dye-sensitized solar cells are generally comprised of a transparent conductive substrate 10, a photoabsorption layer 20, a counter electrode 70, and an electrolyte 30. The photoabsorption layer may be formed by absorbing photosensitive dyes 21a to metal oxide nanoparticles 22 having wide band gap energy, and the counter electrode may be formed by coating a platinum (Pt) 50 on a transparent conductive substrate 10.

In dye-sensitized solar cells, photosensitive dyes absorb incident solar rays and turn to an excited state, thereby transmitting electrons to the conduction band of metal oxide. The transmitted electrons move to an electrode and flow to external circuit to transfer the electrical energy, and turn to lower energy state according to the energy transfer and moves to the counter electrode. Then, the photosensitive dyes are provided with electrons from the electrolyte solution 30 as much as the dyes transfer to the metal oxide, and turn to the original state, wherein the electrolyte receives electrons from the counter electrode and transfer them to photosensitive dyes 21a via an oxidation-reduction process.

In order to absorb light in a broad wavelength range, single dye having a wide absorption wavelength range may be developed, or two or more nanoparticle layers may be deposited to absorb dyes having different absorption wavelengths. In the latter case, light in a broad wavelength range can be absorbed as shown in FIG. 2, and thus it is possible to control an absorption wavelength range of dye-sensitized solar cells using already developed dyes having various absorption wavelength ranges, thereby improving the efficiency.

However, in order to enable the metal oxide nanoparticle layer to transfer electrons, high temperature sintering process is typically conducted. In addition, because dyes are easily degraded at high temperature, additional sintering of metal oxide nanoparticles may not be conducted after conducting the dye absorption once.

For this reason, conventional dye-sensitized solar cells have used one kind of dye or simply mixed two or more kinds of dyes. And, as shown in FIG. 1B, two or more individual cells respectively comprising dyes absorbing light of different wavelength ranges were layered in order to improve the efficiency. However, such a method is problematic in that two conductive substrates are placed between the photoabsorption layer, thus lowering the transparency which is the advantage of dye-sensitized solar cells, and the amount of light reaching the rear photoabsorption layer is reduced. Moreover, since two individual cells are layered, the efficiency is less compared to a single cell.

### SUMMARY

According to an aspect, there is provided a dye-sensitized solar cell absorbing a multi-wavelength that has a contacted interface structure and that effectively utilizes a broader wavelength range of light, by means of forming nanoparticle layers adsorbed by dyes having same or different absorption wavelength from each other on a photoelectrode and a counter electrode, and contacting the faces thereof.

According to another aspect, there is provided a dye-sensitized solar cell including a photoelectrode comprising a metal oxide nanoparticle layer to which dyes are absorbed, formed on a transparent conductive substrate, a counter electrode comprising a platinum (Pt) layer and a metal oxide nanoparticle layer to which dyes are absorbed, formed on a transparent conductive substrate, for example, in orderly manner, and arranged opposite to the photoelectrode, and an electrolyte provided between the photoelectrode and the counter electrode.

The metal oxide nanoparticle layer formed on the photoelectrode and the metal oxide nanoparticle layer formed on the counter electrode may be placed to face each other and form a contacted interface structure in a single cell.

The dyes of the photoelectrode and the counter electrode may have same or different absorption wavelength ranges.

The counter electrode may further comprise an insulating layer provided between the metal oxide nanoparticle layer and the platinum layer.

The metal oxide nanoparticle layers of the photoelectrode and the counter electrode may include at least one material selected from the group consisting of a titanium (Ti) oxide, a zirconium (Zr) oxide, a strontium (Sr) oxide, a zinc (Zn) oxide, an indium (In) oxide, a lanthanum (La) oxide, a vanadium (V) oxide, a molybdenum (Mo) oxide, a tungsten (W) oxide, a tin (Sn) oxide, a niobium (Nb) oxide, a magnesium (Mg) oxide, an aluminum (Al) oxide, an yttrium (Y) oxide, a scandium (Sc) oxide, a samarium (Sm) oxide, a gallium (Ga) oxide, and a strontium titanium (SrTi) oxide.

The insulating layer may comprise at least one material selected from the group consisting of a titanium (Ti) oxide, a zirconium (Zr) oxide, a strontium (Sr) oxide, a zinc (Zn) oxide, an indium (In) oxide, a lanthanum (La) oxide, a vanadium (V) oxide, a molybdenum (Mo) oxide, a tungsten (W) oxide, a tin (Sn) oxide, a niobium (Nb) oxide, a magnesium (Mg) oxide, an aluminum (Al) oxide, an yttrium (Y) oxide, a scandium (Sc) oxide, a samarium (Sm) oxide, a gallium (Ga) oxide, and a strontium titanium (SrTi) oxide.

According to still another aspect, there is provided a method of preparing a dye-sensitized solar cell, the method including (a) forming a metal oxide nanoparticle layer by coating a nanoparticle paste on a face of a transparent conductive substrate and heat-treating the same, (b) preparing a photoelectrode by adsorbing a dye to the metal oxide nanoparticle layer of (a), (c) forming a metal oxide nanoparticle layer by coating a nanoparticle paste on a transparent conductive substrate where a platinum layer is formed on and heat-treating the same, (d) preparing a counter electrode by adsorbing a dye of which the absorption wavelength range is same as or different from the dye of (b) to the metal oxide nanoparticle layer of (c), and (e) placing the metal oxide nanoparticle layers of the photoelectrode and the counter electrode to face each other so as to form a contacted interface of the nanoparticle layers and providing an electrolyte therein.

The method may further include forming an insulating layer before forming the metal oxide nanoparticle layer on the transparent conductive substrate in (c).

The nanoparticle paste may comprise nanoparticles of metal oxide, a binder polymer, and a solvent.

The heat-treating may be carried out at 400 to 550° C. for 10 to 120 minutes.

At least one dye may be adsorbed to the surface of the nanoparticles of metal oxide by dipping the substrates where the metal oxide nanoparticle layer is formed on in a solution comprising same or different dyes from each other so as to control the absorption wavelength range.

Other features and aspects will be apparent from the following detailed description, the drawings, and the claims.

### BRIEF DESCRIPTION OF THE DRAWINGS

FIG. 1A is a diagram illustrating a structure of a dye-sensitized solar cell.

FIG. 1B is a diagram illustrating a structure of a dye-sensitized solar cell having a tandem structure.

FIG. 2 is a diagram illustrating a contacted layered structure of a transparent dye-sensitized solar cell according to an exemplary embodiment.

FIG. 3 is a diagram illustrating an absorbance of adsorption dyes having different absorption wavelength and an absorbance of a single adsorption dye that is used in a conventional solar cell.

FIG. 4 is a graph illustrating Incident Photon to Current Conversion Efficiencies (IPCE) results of Example 1, Comparative Example 1, and Experimental Example 2.

FIG. 5 is a graph illustrating Incident Photon to Current Conversion Efficiencies (IPCE) results of Examples 2 to 5.

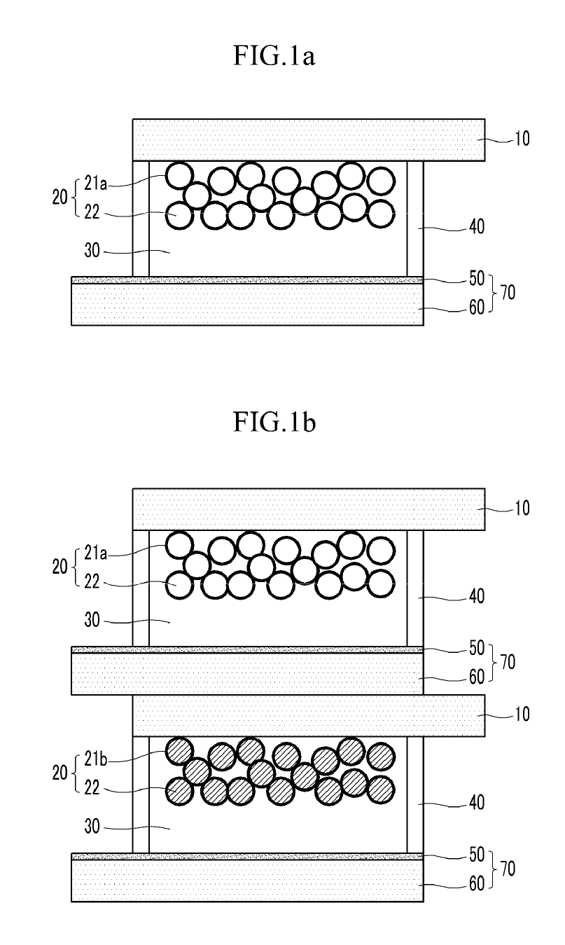

Throughout the drawings and the detailed description, unless otherwise described, the same drawing reference numerals will be understood to refer to the same elements, features, and structures. The relative size and depiction of these elements may be exaggerated for clarity, illustration, and convenience.

<Explanations for Reference Numerals of the Drawings>

10, 60: transparent conductive substrates

20: photoabsorption layer

21a: dye

21b: dye same as or different from 21a

22: metal oxide nanoparticles

30: oxidation/reduction electrolyte

40: binder resin

50: platinum layer

70: counter electrode

110, 210: transparent conductive substrates

120: photoabsorption layer

121a: dye

121b: dye same as or different from 121a

122: metal oxide nanoparticles

100: photoelectrode

200: counter electrode

220: platinum layer

240: insulating layer

300: oxidation/reduction electrolyte

400: binder resin

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

While the conventional technique adsorb a single dye to a single oxide layer, a dye-sensitized solar cell absorbing multi-wavelength is provided described below.

Although a method of adsorbing a first dye to a first oxide layer, forming a second oxide layer thereon, and adsorbing a second dye to the second oxide layer has been proposed as a method for absorbing multi-wavelength, the oxide layer is formed typically by heat-treating at 450-500° C. for 30 minutes to 1 hour, and the first dye does not exist at the end because the first dye is decomposed by the heat-treating process at the high temperature (generally, dyes are decomposed at 120° C. or more) during the forming of the second oxide layer. Therefore, it has been difficult to provide a structure absorbing multi-wavelength by means of layering oxides.

Furthermore, a method of forming an oxide layer to a counter electrode coated by platinum (Pt) has not been proposed and is proposed by teachings herein.

According to an aspect, the instant inventors discovered in the process of developing a dye-sensitized solar cell for absorbing multi-wavelength, that if an oxide layer is formed on a counter electrode, a first dye and a second dye can exist together in a dye-sensitized solar cell and it is possible to absorb a broad wavelength of solar rays.

A solar cell structure according to an exemplary embodiment may also include an insulating layer between the counter electrode and the metal oxide nanoparticle layer.

The photoelectrode may mean an electrode having a metal oxide nanoparticle layer to which dyes are adsorbed, formed on a general transparent conductive substrate. The counter electrode may mean an electrode having a metal oxide nanoparticle layer to which dyes are adsorbed, formed on a platinum layer that is formed on a transparent conductive substrate.

Hereinafter, a dye-sensitized solar cell according to an exemplary embodiment and a method of preparing the same are further explained below by referring to the figures.

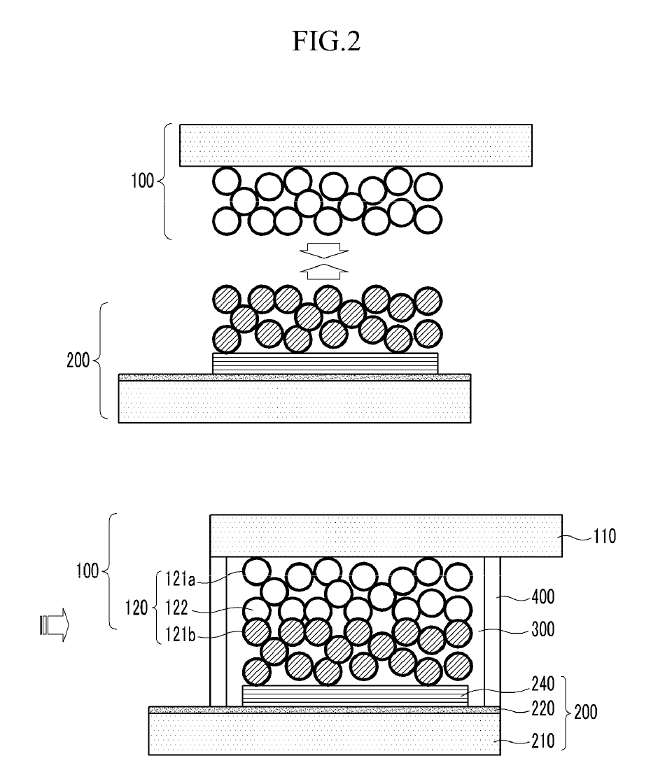

FIG. 2 shows a structure of a transparent dye-sensitized solar cell according to an exemplary embodiment.

As shown in FIG. 2, the exemplary dye-sensitized solar cell comprises a photoelectrode 100 having a metal oxide nanoparticles 122 adsorbed by a dye 121a on a transparent conductive substrate 110, a counter electrode 200 that is placed to face the photoelectrode 100 and comprises a platinum layer 240 and a metal oxide nanoparticles 122 adsorbed by a dye 121b on a transparent conductive substrate 210 in order, and an electrolyte 300 provided between the photoelectrode 100 and the counter electrode 200. The photoelectrode 100 and the counter electrode 200 may be adhered by a binder resin 400. An insulating layer 220 may be provided between the platinum layer 240 and the substrate 210. The parts having the metal oxide nanoparticles 122 adsorbed by the dyes 121a, 121b in the photoelectrode 100 and the counter electrode 200 may take the role of a photoabsorption layer.

Materials having same or different absorption wavelength range may be used as the dyes of the photoelectrode 100 and the counter electrode 200, and for example, materials having different absorption wavelength range may be used.

Referring to FIG. 2, the exemplary dye-sensitized solar cell absorbing multi-wavelength may be prepared by: (a) coating nanoparticle pastes on transparent conductive substrates for a photoelectrode and a counter electrode coated by a platinum, respectively; (b) heat-treating and sintering the same; (c) adsorbing same or different dyes to each metal oxide nanoparticle layer; and (d) placing the two metal oxide nanoparticle layers to face each other so as to contact the faces thereof.

The nanoparticle paste may be prepared by, for example, mixing the metal oxide nanoparticles and a solvent so as to prepare a colloidal solution having a viscosity of 5×10⁴ to 5×10⁵ cps in which the metal oxide particles are dispersed, mixing a binder resin and the solution, and eliminating the solvent from the solution with a rotor evaporator at 40 to 70° C. for 30 minutes to 1 hour. The metal oxide nanoparticles may be prepared by a hydrothermal synthesis, or commercial metal oxide nanoparticles may be used as the nanoparticles. Furthermore, the mixing ratio of the metal oxide nanoparticles, the binder resin, and the solvent is not particularly limited, however, the weight ratio of the metal oxide:terpineol:ethylcellulose:lauric acid may be 1:2 to 6:0.2 to 0.5:0.05 to 0.3 according to an exemplary embodiment.

The kinds of the binder resin are not particularly limited and common polymers for a binder may be used. For example, a polymer that does not remain organic materials after heat-treating may be used. A polyethyleneglycol (PEG), a polyethyleneoxide (PEO), a polyvinylalcohol (PVA), a polyvinylpyrrolidone (PVP), ethylcellulose, and so on may be used according to an exemplary embodiment. The prepared paste may be dispersed once again by introducing the paste into a 3 roll-pulverizer where 3 ceramic rolls rotate with a toothed wheel and post-processing the same, in order to disperse the prepared paste more uniformly.

At least one metal oxide selected from the group consisting of Ti, Zr, Sr, Zn, In, Yr, La, V, Mo, W, Sn, Nb, Mg, Al, Y, Sc, Sm, and Ga, or a complex oxide thereof may be used as the metal oxide nanoparticles. And for example, the metal oxide nanoparticles may be selected from the group consisting of a titanium oxide (TiO₂), a zinc oxide (ZnO), a tin oxide (SnO₂), and a tungsten oxide (WO₃).

The size of the metal oxide nanoparticle may be 500 nm or less, and may be 1 nm to 100 nm, in an average diameter.

The solvent is not particularly limited if it can be used for preparing a colloidal solution, and ethanol, methanol, terpineol, lauric acid, tetrahydrofuran (THF), water, and so on may be used for example.

As an example of the constituents of the metal oxide nanoparticle paste, a composition comprising a titanium oxide, terpineol, ethylcellulose, and lauric acid, or a composition comprising a titanium oxide, ethanol, and ethylcellulose may be used.

Furthermore, according to an exemplary embodiment, the metal oxide nanoparticle paste prepared as in the above may be coated on the transparent conductive substrate 110, and heat-treated at 400 to 550° C. for 10 to 120 minutes, for example, at a temperature of 450 to 500° C. for about 30 minutes, in an air or an oxygen surrounding, so as to prepare the metal oxide nanoparticle layer that is used for the photoelectrode 100. The photoelectrode 100 where the photoabsorption layer 120 comprising the metal oxide nanoparticles 122 is formed may be prepared through the process.

The nanoparticle layer may formed on the counter electrode according to the following exemplary method, in order to prepare the counter electrode 200 that is needed for the contacted structure. That is, the platinum layer 220 is prepared by coating the platinum solution on the transparent conductive substrate 210, and heat-treating the same at a temperature of about 400° C. Subsequently, the counter electrode having the metal oxide nanoparticles 122 is prepared by coating the prepared metal oxide nanoparticle paste thereon, and heat-treating the same at a high temperature in an air or an oxygen surrounding. At this time, the insulating layer 240 may further be formed between the counter electrode and the metal oxide nanoparticle layer. When the insulating layer is formed, the process may be proceeded by coating an insulating material paste on the counter electrode, heat-treating the same at a high temperature so as to form the insulating layer, and forming the nanoparticle layer on the insulating layer according to the exemplary method above. Any materials having a broad band gap, such as titanium oxides (TiOₓ), zirconium oxides (ZrOₓ), silicone oxides (SiOₓ), and the like, may be used to the insulating layer.

The transparent conductive substrate 110, 210 may be selected from what is common in the art, and for example, a transparent plastic substrate comprising any one of a polyethyleneterephthalate (PET), a polyethylenenaphthalate (PEN), a polycarbonate (PC), a polypropylene (PP), a polyimide (PI), and a triacetylcellulose (TAC), or a glass substrate coated by a conductive film comprising any one of a indium tin oxide (ITO), a fluorine tin oxide (FTO), ZnO—Ga₂O₃, ZnO—Al₂O₃, and SnO₂—Sb₂O₃ may be used, however, it is not limited to or by them.

Furthermore, the dye materials 121a, 121b may be adsorbed to the metal oxide nanoparticle layers those are formed on the photoelectrode and the counter electrode in order to generate a photocharge, after the metal oxide nanoparticle layers are formed on each photoelectrode and counter electrode.

The dyes used in the metal oxide nanoparticle layers of the photoelectrode and the counter electrode may be the dyes having same or different absorption wavelength from each other in order to absorb multi-wavelength (121a, 121b in FIG. 2). According to an exemplary embodiment, the dye materials include the material that comprises a Ru complex or an organic material and can absorb visible light, and for example, Ru(4,4′-dicarboxy-2,2′-bipyridine)₂(NCS)₂ may be used. Furthermore, an organic photosensitive dye TAstCA, 2-cyano-3-(4-(diphenylamino)styryl)phenyl)acrylic acid), and the like may be used as the dye material.

As a method of adsorbing the dyes, a common method used in a general dye-sensitized solar cell may be used, and a method of dipping the photoelectrode where the metal oxide nanoparticle layer is formed into a dispersion solution comprising the dye, and passing at least 12 hours so as to adsorb the same spontaneously, for example, however, it is not particularly limited thereto. The solvent for dispersing the dye is not particularly limited, however, acetonitrile, dichloromethane, an alcohol-based solvent, and the like may be used. After adsorbing the dye, a process to wash the dye not adsorbed according to a solvent washing method and the like may further be included.

For example, the step of adsorbing the dyes may be prepared by dipping the photoelectrode substrate and the counter electrode substrate where the metal oxide nanoparticle porous layers are formed into the solutions comprising same or different photosensitive dyes for 1 to 48 hours, so as to adsorb at least one dye to the surface of the porous layers, and control the absorption wavelength range.

The dye-sensitized solar cell absorbing multi-wavelength having a contacted interface structure in the photoabsorption layer 120 adsorbed by at least one dye may be prepared by uniting two electrodes 110, 200 that are prepared by the above methods.

Though the electrolyte 300 is illustrated as one layer in FIG. 2 for convenience, the electrolyte is in fact uniformly dispersed in the metal oxide nanoparticle layer 122 that is a porous layer in the space of the photoabsorption layer 120.

A dye-sensitized solar cell according to an exemplary embodiment may be characterized in the structures of the counter electrode 200 that comprises the photoabsorption layer having a nanoparticle layer on its one side, and the united structure of said photoabsorption layer and the photoabsorption layer of the photoelectrode 100 of a conventional dye-sensitized solar cell comprising the nanoparticle layer, and thus the technical features of the electrolyte 300 except the same may include conventional features in the related art to which the exemplary embodiment pertains, and it may be prepared by using a conventional method and thus it is not particularly limited to or by them.

For example, the electrolyte 300 may be an iodide/triodide pair, and what can receive electrons from the counter electrode 70 and transfer the same to the dye of the photoabsorption layer 120 may be used.

The dye-sensitized solar cell having the technical features may be prepared by placing and uniting the nanoparticle layers of the photoelectrode 100 and the counter electrode 200 that are prepared by, for example, the above methods to face each other, and providing the electrolyte 300 therein. The binder resin 400 may be formed by a heat pressing method or a UV-curing method. Furthermore, when uniting the two electrodes, an adhesive material may be used in order to make the electron transportation easy at the interface, and the adhesive material may include the metal oxide precursor or the metal oxide nanoparticles disclosed above.

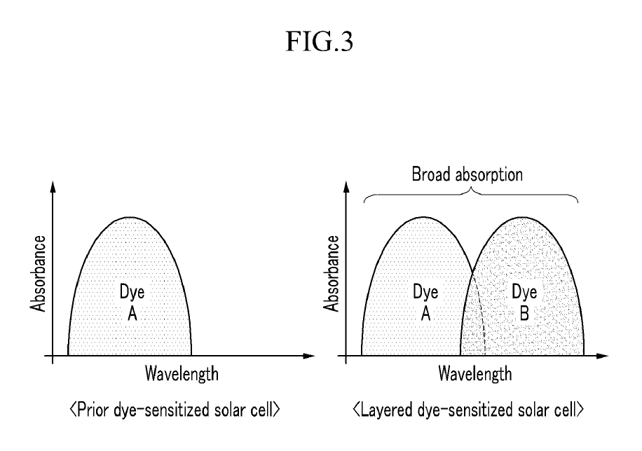

As illustrated in FIG. 3, the dye-sensitized solar cell according to an exemplary embodiment comprises the photoabsorption layer having the metal oxide nanoparticle layer adsorbed by the dye even in the counter electrode, and may absorb broad solar rays in comparison with a common dye-sensitized solar cell by contacting the surface to the photoabsorption layer of the photoelectrode.

Therefore, it is possible to prepare a solar cell having improved efficiency by forming the nanoparticle layers adsorbed by the dyes having same or different photoabsorption wavelength in a single cell so as to absorb broader wavelength range of light and improve the photocurrent density.

The following examples are provided as further illustrations and it is understood that embodiments are not limited thereto.

### EXAMPLE 1

(Preparation of a Dye-Sensitized Solar Cell Having a Contacted Layered Structure)

Glass substrates coated by FTO were prepared as the substrates for the photoelectrode and the counter electrode.

After masking the conductive face of the substrate for the counter electrode by using an adhesive tape in an area of 1.5 cm², H₂PtCl₆ solution was coated thereon by using a spin coater, and it was heat-treated at 500° C. for 30 minutes so as to prepare the counter electrode. Subsequently, the conductive face of the counter electrode was masked by using the adhesive tape in an area of 1.5 cm². A paste for the insulating layer comprising huge titanium particles having a diameter of about 300 nm, a polymer for a binder (ethylcellulose), and a solvent (terpineol) in a weight ratio of 1:0.2-0.6:2-6 was prepared. And then, the paste was coated on the substrate by a doctor blade method, and the substrate was heat-treated at 500° C. for 30 minutes.

The counter electrode where the insulating layer was formed and the conductive face of the substrate for the photoelectrode were masked by using the adhesive tape in an area of 1.5 cm².

Subsequently, metal oxide nanoparticle pastes comprising titanium oxide nanoparticles (average diameter: 20 nm), a polymer for a binder (ethylcellulose), and a solvent (terpineol) in a weight ratio of 1:0.2-0.6:2-6 were coated on said two substrates by the doctor blade method, and the substrates were heat-treated at 500° C. for 30 minutes so as to form the metal oxide nanoparticle layers. At this time, the thickness of the titanium oxide nanoparticle layer of each electrode was about 5 μm, and the thickness of the insulating layer was about 4 μm.

Subsequently, the photoelectrode was prepared by dipping the substrate for the photoelectrode into an ethanol solution comprising 0.5 mM of TAstCA represented by the following Chemical Formula 1 as an organic photosensitive dye for 12 hours so as to adsorb the photosensitive dye to the surface of the porous layer.

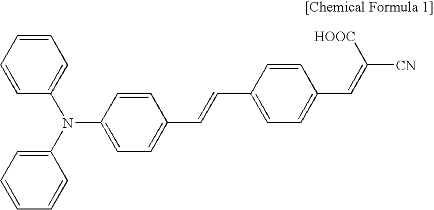

The counter electrode was prepared by dipping the substrate having the counter electrode where the nanoparticle layer was formed into an ethanol solution comprising 0.5 mM of [Ru(4,4′-dicarboxy-2,2′-bipyridine)₂(NCS)₂] as a photosensitive dye for 12 hours so as to adsorb the photosensitive dye to the surface of the porous layer.

(Forming a Contacted Structure, Injecting an Electrolyte, and Sealing the Cell)

The dye-sensitized solar cell absorbing multi-wavelength having a contacted interface structure was prepared by placing and uniting the nanoparticle layers of the photoelectrode and the counter electrode to face each other, injecting an acetonitrile electrolyte comprising LiI (0.5M) and I (0.05M) into the space between the layers, and sealing the same.

### COMPARATIVE EXAMPLE 1

A solar cell was prepared by forming a titanium oxide nanoparticle layer having a thickness of about 10 μm on a conductive substrate, preparing the photoelectrode by adsorbing an organic photosensitive dye TAstCA only, and using a counter electrode comprising only a platinum without the photoabsorption layer nor the insulating layer, in order to identify whether the structure according to an exemplary embodiment attributes to the improvements of the current or efficiency.

### EXAMPLES 2 TO 5

(Verification of Electron Generation from the Counter Electrode)

Dye-sensitized solar cells were prepared by adsorbing a dye only to a nanoparticle layer of a counter electrode, after preparing titanium oxide nanoparticle layers to be used to the photoelectrode and the counter electrode, according to Example 1, in order to recognize the electron transportation from the counter electrode. At this time, the thickness of the prepared titanium oxide nanoparticle layers were varied into 3 μm (Example 2 in Table 2), 7 μm (Example 3 in Table 2), 9 μm (Example 4 in Table 2), and 14 μm (Example 5 in Table 2), and the effects due to their thicknesses were observed.

### EXPERIMENTAL EXAMPLE 1

Open-circuit voltage, photocurrent density, energy conversion efficiency, and fill factor of each dye-sensitized solar cell prepared in Examples 1, 2 to 5, and Comparative Example 1 were measured by the following method, and the results are listed in the following Tables 1 and 2.

[Open-Circuit Voltage (V) and Photocurrent Density (mA/cm²)]

Open-circuit voltage and photocurrent density were measured by using Keithley SMU2400.

[Energy Conversion Efficiency (%), and Fill Factor (%)]

Energy conversion efficiency was measured by using a solar simulator (consisting of Xe lamp [300 W, Oriel], AM1.5 filter, and Keithley SMU2400) of 1.5 AM 100 mW/cm², and fill factor was calculated from the conversion efficiency according to the following Calculation Formula.

$$Fill factor ( \% ) = \frac{{( J \times V )}_{max}}{{J}_{sc} \times {V}_{oc}} \times 100 \qquad [ Calculation Formula ]$$

wherein J is y-axis value of conversion efficiency curve, V is x-axis value of conversion efficiency curve, and J_{sc} and V_{oc} are intercepts of each axis.

### EXPERIMENTAL EXAMPLE 2

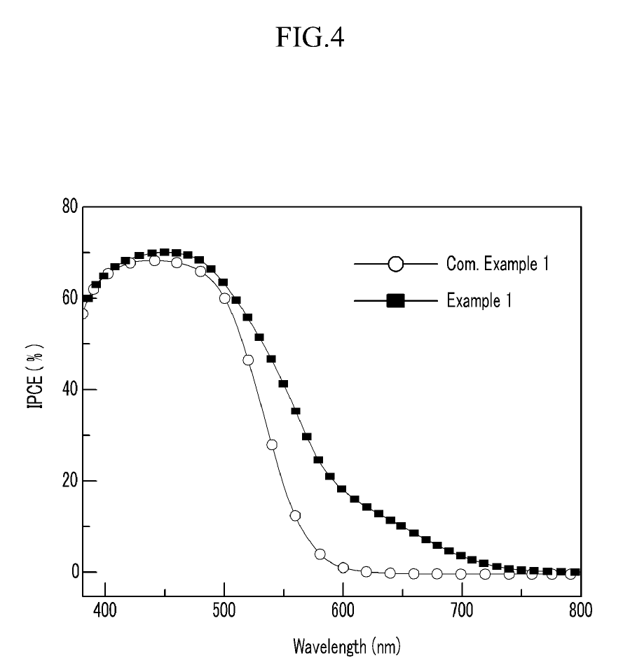

Incident Photon-to-Current Conversion Efficiencies (IPCE) of the dye-sensitized solar cells prepared in Example 1 and Comparative Example 1 were measured, and the results are illustrated in FIG. 4.

### EXPERIMENTAL EXAMPLE 3

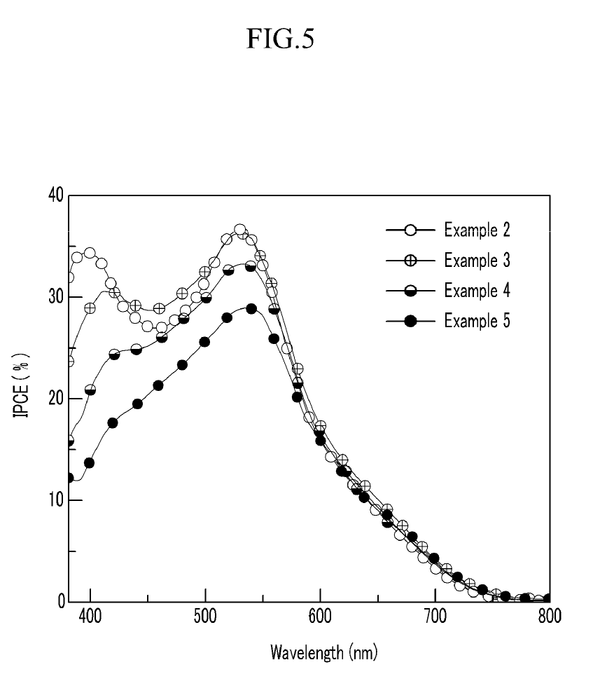

Incident Photon-to-Current Conversion Efficiencies (IPCE) of the dye-sensitized solar cells prepared in Examples 2 to 5 were measured, and the results are illustrated in FIG. 5.

TABLE 1

| | Photocurrent | Open-circuit | Fill factor | Efficiency |
|---|---|---|---|---|
| Classification | density (mA/cm²) | voltage (mV) | (%) | (%) |
| Example 1 | 9.7 | 741 | 53.8 | 3.86 |
| Comparative | 7.2 | 746 | 60.6 | 3.25 |
| Example 1 | | | | |

As shown in Table 1, the dye-sensitized solar cell (Example 1) according to an exemplary embodiment absorbs a broad wavelength range of light, and thus its current density rises, and the efficiency is increased in comparison with the dye-sensitized solar cell having a general structure (Comparative Example 1).

Furthermore, from the result of Incident Photon-to-Current Conversion Efficiency shown in FIG. 4, it can be seen that the conversion efficiency of the dye-sensitized solar cell comprising TAstCA and [Ru(4,4′-dicarboxy-2,2′-bipyridine)₂(NCS)₂] as the dyes rises in all wavelength range in comparison with the dye-sensitized solar cell comprising TAstCA only (Comparative Example 1). For example, the conversion efficiency is represented even in the wavelength range of 600 nm or more where the TAstCA does not absorb, in case of the instant embodiment. It can be recognized from the Incident Photon-to-Current Conversion curve of the dye-sensitized solar cell (Experimental Example 1) comprising [Ru(4,4′-dicarboxy-2,2′-bipyridine)₂(NCS)₂] that the absorption is represented by [Ru(4,4′-dicarboxy-2,2′-bipyridine)₂(NCS)₂] adsorbed to the counter electrode.

TABLE 2

| | Photocurrent | | Fill | | Thick- |
|---|---|---|---|---|---|
| | density | Open-circuit | factor | Efficiency | ness |
| Classification | (mA/cm²) | voltage (mV) | (%) | (%) | (μm) |
| Example 2 | 5.6 | 740 | 68.2 | 2.84 | 3 |
| Example 3 | 5.5 | 735 | 69.3 | 2.81 | 7 |
| Example 4 | 5.1 | 732 | 69.2 | 2.59 | 9 |
| Example 5 | 4.6 | 734 | 65.5 | 2.20 | 14 |

As shown in Table 2, whether the current generated in the counter electrode transfers electrons easily through the counter electrode is recognized by the method of not adsorbing the dye to the photoelectrode. In addition, it is also recognized that the current density decreases little by little as the thickness of the titanium oxide nanoparticle layer of the photoelectrode increases.

Furthermore, it can be seen from the result of Incident Photon-to-Current Conversion Efficiency (FIG. 5) that the conversion efficiency decreases in the wavelength range of 600 nm or less as the thickness increases. From this, it can be seen that the decrease of the current density due to the thickness is caused by the decrease of the transmittance due to the titanium oxide nanoparticle layer of the photoelectrode.

According to certain examples described above, it is recognized that the current generated from a counter electrode is effectively transferred to a photoelectrode in a contacted interface structure of a nanoparticle layer. Furthermore, when different dyes are adsorbed to the photoelectrode and the counter electrode, it is possible to utilize a broader wavelength of light than a electrode structure adsorbed by a single dye.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A dye-sensitized solar cell comprising:
a photoelectrode comprising a metal oxide nanoparticle layer to which dyes are absorbed, formed on a transparent conductive substrate;
a counter electrode comprising a platinum (Pt) layer and a metal oxide nanoparticle layer to which dyes are absorbed, formed on a transparent conductive substrate and arranged opposite to the photoelectrode; and
an electrolyte provided between the photoelectrode and the counter electrode.

2. The dye-sensitized solar cell according to claim 1, wherein the metal oxide nanoparticle layers of the photoelectrode and the counter electrode are placed to face each other and form a contacted interface structure in a single cell.

3. The dye-sensitized solar cell according to claim 1, wherein the dyes of the photoelectrode and the counter electrode have same or different absorption wavelength ranges.

4. The dye-sensitized solar cell according to claim 1, wherein the counter electrode further comprises an insulating layer provided between the metal oxide nanoparticle layer and the platinum layer.

5. The dye-sensitized solar cell according to claim 1, wherein the metal oxide nanoparticle layers of the photoelectrode and the counter electrode include at least one material selected from the group consisting of a titanium (Ti) oxide, a zirconium (Zr) oxide, a strontium (Sr) oxide, a zinc (Zn) oxide, an indium (In) oxide, a lanthanum (La) oxide, a vanadium (V) oxide, a molybdenum (Mo) oxide, a tungsten (W) oxide, a tin (Sn) oxide, a niobium (Nb) oxide, a magnesium (Mg) oxide, an aluminum (Al) oxide, an yttrium (Y) oxide, a scandium (Sc) oxide, a samarium (Sm) oxide, a gallium (Ga) oxide, and a strontium titanium (SrTi) oxide.

6. The dye-sensitized solar cell according to claim 4, wherein the insulating layer comprises at least one material selected from the group consisting of a titanium (Ti) oxide, a zirconium (Zr) oxide, a strontium (Sr) oxide, a zinc (Zn) oxide, an indium (In) oxide, a lanthanum (La) oxide, a vanadium (V) oxide, a molybdenum (Mo) oxide, a tungsten (W) oxide, a tin (Sn) oxide, a niobium (Nb) oxide, a magnesium (Mg) oxide, an aluminum (Al) oxide, an yttrium (Y) oxide, a scandium (Sc) oxide, a samarium (Sm) oxide, a gallium (Ga) oxide, and a strontium titanium (SrTi) oxide.

7. A method of preparing a dye-sensitized solar cell, the method comprising:
(a) forming a metal oxide nanoparticle layer by coating a nanoparticle paste on a face of a transparent conductive substrate and heat-treating the same;
(b) preparing a photoelectrode by adsorbing a dye to the metal oxide nanoparticle layer of (a);
(c) forming a metal oxide nanoparticle layer by coating a nanoparticle paste on a transparent conductive substrate where a platinum layer is formed on and heat-treating the same;
(d) preparing a counter electrode by adsorbing a dye of which the absorption wavelength range is same as or different from the dye of (b) to the metal oxide nanoparticle layer of (c); and
(e) placing the metal oxide nanoparticle layers of the photoelectrode and the counter electrode to face each other so as to form a contacted interface of the nanoparticle layers and providing an electrolyte therein.

8. The method of preparing a dye-sensitized solar cell according to claim 7, further comprising forming an insulating layer before forming the metal oxide nanoparticle layer on the transparent conductive substrate in (c).

9. The method of preparing a dye-sensitized solar cell according to claim 7, wherein the nanoparticle paste comprises nanoparticles of metal oxide, a binder polymer, and a solvent.

10. The method of preparing a dye-sensitized solar cell according to claim 7, wherein the heat-treating is carried out at 400 to 550° C. for 10 to 120 minutes.

11. The method of preparing a dye-sensitized solar cell according to claim 7, wherein at least one dye is adsorbed to the surface of the nanoparticles of metal oxide by dipping the substrates where the metal oxide nanoparticle layer is formed on in a solution comprising same or different dyes from each other so as to control the absorption wavelength range.
